(19) United States
(12) Patent Application Publication
(10) Pub. No.: US 2025/0137131 A1
(43) Pub. Date: May 1, 2025

(54) DEPOSITION APPARATUS AND METHOD OF DEPOSITING SUBSTRATE

(71) Applicant: SAMSUNG ELECTRONICS CO., LTD., SUWON-SI (KR)

(72) Inventors: Minju LEE, Suwon-si (KR); Daihong KIM, Suwon-si (KR); Sangho RHA, Suwon-si (KR); Juchan BANG, Suwon-si (KR); Seungjae SIM, Suwon-si (KR); Mingyu JEON, Suwon-si (KR)

(21) Appl. No.: 18/670,957

(22) Filed: May 22, 2024

(30) Foreign Application Priority Data
Oct. 30, 2023 (KR) 10-2023-0146825

(51) Int. Cl. C23C 16/458; C23C 16/455; C23C 16/56

(52) U.S. Cl. CPC C23C 16/458; C23C 16/45565; C23C 16/56

(57) ABSTRACT

A deposition apparatus includes: a chamber; a support unit within the chamber and including a chuck and a driving member, wherein a substrate is seated on the chuck, wherein the chuck has a first process position and a second process position, wherein the first process position is for processing the substrate in a first process, wherein the second process position is for processing the substrate in a second process, wherein the driving member moves the chuck between the first process position and the second process position; a showerhead supplying process gas toward the substrate, when the chuck is located in the first process position; a power supply unit supplying power to generate plasma between the chuck and the showerhead; and a first ultraviolet lamp disposed in the chamber and emitting ultraviolet rays toward the substrate, when the chuck is located in the second process position.

### CROSS-REFERENCE TO RELATED APPLICATION

This application claims priority under 35 U.S.C. 119 to Korean Patent Application No. 10-2023-0146825 filed on Oct. 30, 2023 in the Korean Intellectual Property Office, the disclosure of which is incorporated by reference herein in its entirety.

### TECHNICAL FIELD

Example embodiments of the present inventive concept relate to a deposition apparatus and a method of depositing a substrate.

### DISCUSSION OF THE RELATED ART

To manufacture a semiconductor device, multiple processes such as a deposition process, a lithography process, an etching process, a cleaning process, and the like may be performed, and multiple devices may be used to perform the multiple processes. For example, representative methods for forming a thin film on a substrate in a deposition process may include chemical vapor deposition (CVD) and atomic layer deposition (ALD). In CVD and ALD processes, various reactants may be used to form a thin film on the surface of a substrate. For example, in the case of a plasma enhanced (PE)-CVD process, when doping an interlayer insulating film or the like on the substrate, defects such as a cusping phenomenon may occur due to incomplete bonding between a bottom growth region and a side growth region due to linearity of plasma. To prevent such defects, an annealing process may be performed to activate the film by heating the substrate on which the thin films are deposited in the deposition process.

### SUMMARY

According to an example embodiment of the present inventive concept, a deposition apparatus includes: a chamber; a support unit within the chamber and including a chuck and a driving member, wherein a substrate is seated on the chuck, wherein the chuck has a first process position and a second process position, wherein the first process position is for processing the substrate in a first process, wherein the second process position is located below the first process position and is for processing the substrate in a second process, wherein the driving member is connected to the chuck and moves the chuck between the first process position and the second process position; a showerhead disposed to face the chuck and supplying process gas toward an upper surface of the substrate that is seated on the chuck, when the chuck is located in the first process position; a power supply unit connected to the showerhead and supplying power to generate plasma between the chuck and the showerhead; and a first ultraviolet lamp disposed above the chuck in the chamber and emitting ultraviolet rays toward the upper surface of the substrate that is seated on the chuck, when the chuck is located in the second process position.

According to an example embodiment of the present inventive concept, a deposition apparatus includes: a chamber having a plurality of processing areas; a transfer arm within the chamber and transferring a substrate to the plurality of processing areas; a support unit in each of the processing areas, and including a chuck and a driving member, wherein a substrate is mounted on the chuck, wherein the chuck has a deposition position and an annealing position, wherein the deposition position is for a deposition process of the substrate, wherein the annealing position is located below the deposition position and is for an annealing process of the substrate, and wherein the driving member is connected to the chuck and moves the chuck between the deposition position and the annealing position; a showerhead disposed to be opposite to the chuck in the chamber and supplying process gas toward an upper surface of the substrate that is seated on the chuck, when the chuck is located in the deposition position; a power supply unit connected to the showerhead and supplying power to generate plasma in a processing area that is between the chuck and the showerhead; and an ultraviolet lamp disposed in the chamber and emitting ultraviolet rays toward the upper surface of the substrate that is seated on the chuck, when the chuck is located in the annealing position.

According to an example embodiment of the present inventive concept, a method of depositing a substrate includes: a deposition operation of depositing a substrate that is mounted on a chuck, when the chuck is located in a first process position within a chamber; and an annealing operation of lowering the chuck within the chamber after the deposition operation is performed and emitting ultraviolet rays toward an upper surface of the substrate that is seated on the chuck, when the chuck is located in a second process position that is lower than the first process position, wherein the deposition operation and the annealing operation are repeatedly performed multiple times within the chamber.

### BRIEF DESCRIPTION OF DRAWINGS

The above and other aspects of the present inventive concept will become more apparent by describing in detail example embodiments thereof, with reference to the accompanying drawings, in which:

FIG. 1 is a schematic cross-sectional view illustrating a deposition apparatus positioned in a first process position according to an example embodiment of the present inventive concept;

FIG. 2 is a schematic diagram illustrating a deposition apparatus positioned in a second process position according to an example embodiment of the present inventive concept;

FIG. 3 is a schematic diagram illustrating an example of an ultraviolet lamp in a deposition apparatus according to an example embodiment of the present inventive concept;

FIG. 4 is a schematic diagram illustrating a deposition apparatus positioned in a first process position according to an example embodiment of the present inventive concept;

FIG. 5 is a schematic diagram illustrating a deposition apparatus positioned in a second process position according to an example embodiment of the present inventive concept;

FIG. 6 is a plan schematic diagram illustrating an example of a showerhead and an ultraviolet lamp of a deposition apparatus according to an example embodiment of the present inventive concept;

FIG. 7 is a schematic diagram illustrating a deposition apparatus including a chamber with a plurality of processing areas according to an example embodiment of the present inventive concept; and

FIG. 8 is a schematic diagram illustrating a substrate deposition process according to an example embodiment of the present inventive concept.

### DETAILED DESCRIPTION OF THE EMBODIMENTS

Hereinafter, example embodiments of the present inventive concept will be described with reference to the accompanying drawings.

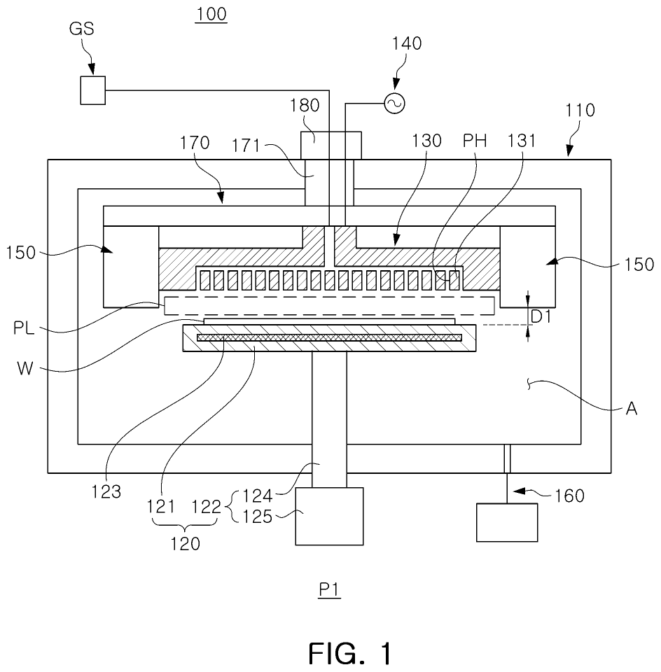

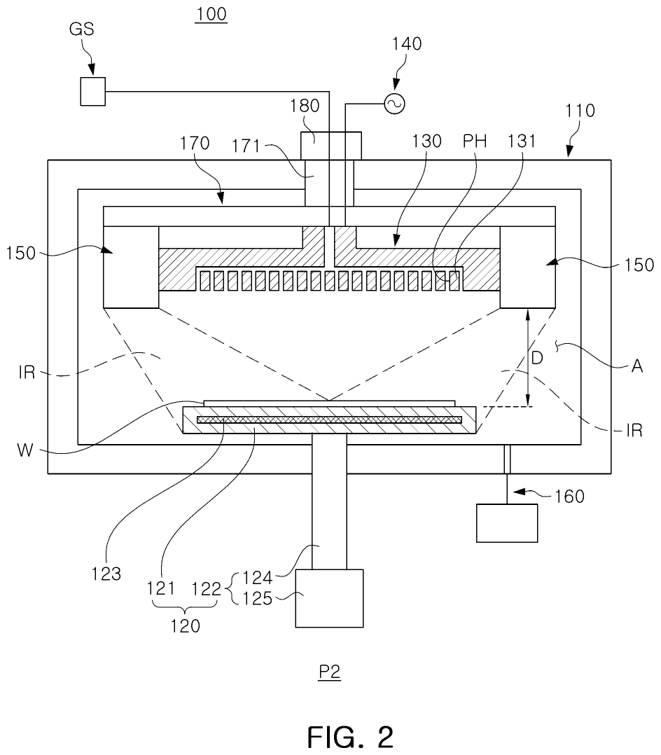

FIG. 1 is a schematic cross-sectional view illustrating a deposition apparatus positioned in a first process position according to an example embodiment of the present inventive concept, and FIG. 2 is a schematic diagram illustrating a deposition apparatus positioned in a second process position according to an example embodiment of the present inventive concept.

Referring to FIGS. 1 and 2, a deposition apparatus 100 according to an example embodiment of the present inventive concept may include a chamber 110, a support unit 120 disposed within the chamber 110, a showerhead 130 disposed within the chamber 110, a power supply unit 140 connected to the showerhead 130, and an ultraviolet lamp 150 disposed within chamber 110.

The deposition apparatus 100 may be a device for forming a thin film on a substrate W, and for example, may be a Chemical Vapor Deposition (CVD) device or an Atomic Layer Deposition (ALD) device.

The substrate W to be processed by the deposition apparatus 100 may be provided on the support unit 120. The substrate W may be, for example, a silicon wafer used in the manufacturing of semiconductor integrated circuits (ICs).

The chamber 110 may provide a space in which a deposition process and an annealing process are performed. The chamber 110 may have one processing area A in which a deposition process and an annealing process are performed. The chamber 110 may include an upper wall, side walls, and a lower wall, and may be configured to surround the processing area A. For example, the upper wall, the side walls, and the lower wall form the processing area A. The support unit 120 may be disposed in the processing area A of the chamber 110, and deposition processing may be performed on the substrate W while the substrate W is seated on the support unit 120 in the chamber 110. Additionally, an annealing treatment may be performed using the ultraviolet lamp 150. An exhaust unit 160 may be connected to the chamber 110 to exhaust reaction by-products and residual gas, which are within the chamber 110, to the outside. For example, the exhaust unit 160 may include a vacuum pump, and reaction by-products and residual gas within the chamber 110 may be discharged externally by vacuum suction force that is generated by the vacuum pump. In an example embodiment of the present inventive concept, the arrangement location, arrangement number, and the like of the exhaust unit 160 may be changed in various manners.

The support unit 120 may be disposed in a lower region within the chamber 110. The support unit 120 may include a chuck 121 and a driving member 122. The chuck 121 may have an upper surface on which the substrate W is mounted, and the driving member 122 is connected to the chuck 121 and lifts the chuck 121. The chuck 121 may be an electrostatic chuck that fixes the substrate W thereto by using an electrostatic force, or may be a vacuum chuck that fixes the substrate W thereto by using vacuum pressure. According to example embodiments of the present inventive concept, the chuck 121 may include a lifting pin on the upper end thereof, and as a result, the substrate W may be lifted and moved into and out of the chamber 110. Additionally, according to example embodiments of the present inventive concept, the chuck 121 may include a heat conductor 123, such as a heating wire, therein, thereby controlling the process temperature. The driving member 122 may include a support shaft 124 and a drive motor 125. The support shaft 124 may support the chuck 121 from the bottom of the chuck 121, and the drive motor 125 is connected to the lower end of the support shaft 124 and lifts and drives the support shaft 124 and the chuck 121. The chuck 121 may have a first process position P1 and a second process position P2. In the first process position P1, the substrate W is subjected to a first process. In the second process position P2, the substrate W is subjected to a second process. The second process position P2 may be located below the first process position P1. For example, when the chuck 121 is in the second process position P2, the chuck 121 is in a lower position when compared to being in the first process position P1. The driving member 122 may elevate the chuck 121 between the first process position P1 and the second process position P2. In the deposition apparatus 100, the chuck 121 is moved upward by the driving member 122, and a deposition process may be performed on the substrate W that is mounted on the upper surface of the chuck 121 when the chuck 121 is located in the first process position P1. In the deposition apparatus 100, the chuck 121 is moved downward by the driving member 122, and an annealing process may be performed on the substrate W that is seated on the upper surface of the chuck 121 when the chuck 121 is located in the second process position P2. Accordingly, the deposition process in the first process position P1 and the annealing process in the second process position P2 may be performed in-situ according to the lifting motion of the chuck 121 within the chamber 110.

The showerhead 130 may be disposed above the support unit 120 within the chamber 110 and may face the support unit 120. The showerhead 130 is disposed to be opposite to the chuck 121 and above the chuck 121 in the chamber 110. The showerhead 130 is connected to a gas source GS to distribute process gas, which is supplied from the gas source GS, and supply the process gas toward the upper surface of the substrate W that is seated on the chuck 121, when the chuck 121 is located in the first process position P1. The showerhead 130 may include a plate 131 having a plurality of spray holes PH through which process gas is sprayed. The plurality of spray holes PH may be disposed radially based on the central area of the showerhead 130.

The power supply unit 140 is connected to the showerhead 130 and may supply power to generate plasma PL in the processing area between the chuck 121 and the showerhead 130. The power supply unit 140 may supply radio frequency (RF) power to the showerhead 130, and generate an electric field due to a voltage difference between the lower and upper portions of the substrate W, and as a result, may generate plasma PL in the processing area between the chuck 121 and the showerhead 130, in which the deposition process is performed on the substrate W. While performing the deposition process, the chuck 121 of the support unit 120 may be grounded. In an example embodiment of the present inventive concept, at least a portion of the process gas is plasmaized, and thus, the process gas may be activated to promote reaction on the substrate W. In an example embodiment of the present inventive concept, the power supply unit 140 may be connected to an electrode that is disposed within the chuck 121 to supply RF power and generate an electric field due to a voltage difference between the bottom and top of the substrate W. As a result, plasma PL may be generated in the processing area that is between the chuck 121 and the showerhead 130, in which the deposition process on the substrate W is performed, and the showerhead 130 may be grounded while performing the deposition process.

The ultraviolet lamp 150 may be disposed above the chuck 121 in the chamber 110 and may emit ultraviolet rays toward the upper surface of the substrate W that is seated on the chuck 121 when the chuck 121 is located in the second process position P2. For example, after performing a deposition process on the substrate W that is seated on the chuck 121, when the chuck 121 is located in the first process position P1 in the chamber 110, the chuck 121 may be moved downward by the driving member 122 and positioned in the second process position P2. In this state, the ultraviolet lamp 150 may perform an annealing process by emitting ultraviolet rays toward the upper surface of the substrate W that is mounted on the chuck 121.

When doping an insulating film or the like on the substrate W during the deposition process, defects such as cusping or the like may occur due to incomplete bonding between the bottom growth region and the side growth region due to the linear nature of the plasma. To alleviate this cusping defect, the ultraviolet lamp 150 may emit ultraviolet rays with a wavelength of about 100 nm to about 400 nm toward the upper surface of the substrate W on which the thin films are deposited. For example, the ultraviolet lamp 150 may emit ultraviolet rays having a wavelength of about 150 nm to about 400 nm toward the upper surface of the substrate W. Accordingly, a stable film without cusping defects may be formed by removing hydrogen that is in the insulating film that is on the upper portion of the substrate W without causing bonding damage to Si—N, Si—O, or the like in the insulating film that is on the upper portion of the substrate W.

In an example embodiment of the present inventive concept, the ultraviolet lamp 150 may be disposed adjacent to the side of the showerhead 130. The ultraviolet lamp 150 may protrude downward beyond the lower surface of the showerhead 130. However, the present inventive concept is not limited thereto, and according to example embodiments of the present inventive concept, the ultraviolet lamp 150 may be disposed on the same plane as the lower surface of the showerhead 130. The ultraviolet lamp 150 may be configured to emit ultraviolet rays toward at least a portion of the upper surface of the substrate W. In an example embodiment of the present inventive concept, when the ultraviolet lamp 150 is configured to emit ultraviolet rays toward a partial region of the upper surface of the substrate W, from the center to the edge, the ultraviolet lamp 150 rotates within the chamber 110 and emits ultraviolet rays toward the upper surface of the substrate W that is seated on the chuck 121, when the chuck 121 is located in the second process position P2. Therefore, the annealing process may be performed uniformly over the entire upper surface of the substrate W.

To implement rotation of the ultraviolet lamp 150 in the example embodiment, the deposition apparatus 100 may further include a rotation support member 170, to which the ultraviolet lamp 150 is coupled, and a rotation drive member 180 that integrally rotates the rotation support member 170 and the ultraviolet lamp 150.

The rotation support member 170 is disposed on the upper portion of the showerhead 130, and the ultraviolet lamp 150 may be coupled to the lower edge region of the rotation support member 170. The rotation support member 170 may be provided with a rotation axis 171 (e.g., a rotation shaft) that is rotatably coupled to the chamber 110. The rotation axis 171 of the rotation support member 170 may be rotatably coupled to the center area of the chamber 110. The rotation support member 170 may have a disk shape and cover the upper portion of the showerhead 130. The rotation drive member 180 is connected to the rotation axis 171 of the rotation support member 170 and may rotate the rotation support member 170 and the ultraviolet lamp 150 about the rotation axis 171. In an example embodiment of the present inventive concept, the rotation drive member 180 may include a drive motor or the like. According to example embodiments of the present inventive concept, the showerhead 130 may or might not rotate together with the rotation support member 170. In an example embodiment of the present inventive concept, the rotation support member 170, the ultraviolet lamp 150, and the showerhead 130 may be rotated integrally about the rotation axis 171 by the rotation drive member 180. In this case, the showerhead 130 may be coupled to the lower part of the rotation support member 170, and the ultraviolet lamp 150 may be coupled to the lower edge region of the rotation support member 170 located around the showerhead 130.

To implement uniform distribution of ultraviolet rays to the substrate W and increase annealing efficiency, the ultraviolet lamp 150 may be provided as a plurality of ultraviolet lamps. The plurality of ultraviolet lamps 150 may be symmetrical to each other at the lower edge region of the rotation support member 170 with respect to the rotation axis 171 of the rotation support member 170 and may be spaced apart from each other at equal intervals. As illustrated in FIGS. 1 and 2, the ultraviolet lamps 150 may be composed of two lamps, and may be symmetrical to each other and spaced apart from each other at opposing lower edge regions of the rotation support member 170 with respect to the rotation axis 171. The two ultraviolet lamps 150 may be configured to emit ultraviolet rays over the entire upper surface of the substrate W mounted on the chuck 121, when the chuck 121 is located in the second process position P2. For example, while performing the annealing process, the two ultraviolet lamps 150 rotate around the rotation axis 171 by the rotation drive member 180, and emit ultraviolet rays to have an irradiation range IR that is illustrated in FIG. 2. Accordingly ultraviolet rays may be spread evenly across the entire upper surface of the substrate W without intensive exposure to only one side of the substrate W, thereby obtaining a uniform annealing effect.

Since the ultraviolet lamp 150 is located on the outer periphery of the showerhead 130 and the substrate W when viewed from the top, to uniformly emit ultraviolet rays to the upper surface of the substrate W, a separation distance D between the chuck 121 and the ultraviolet lamp 150 may be about 15 cm to about 30 cm when the chuck 121 is located in the second process position P2, according to an example embodiment of the present inventive concept. In this case, the separation distance D between the chuck 121 and the ultraviolet lamp 150, when the chuck 121 is located in the second process position P2, may be set to be greater than the separation distance D1 between the chuck 121 and the ultraviolet lamp 150, when the chuck 121 is located in the first process position P1. Accordingly, during the annealing process, a sufficient separation distance D between the chuck 121 and the ultraviolet lamp 150 may be maintained to ensure that ultraviolet rays are uniformly distributed across the entire upper surface of the substrate W, thereby increasing annealing efficiency. However, the present inventive concept is not limited thereto, and depending on the type, structure and arrangement of the ultraviolet lamp 150, the separation distance D between the chuck 121 and the ultraviolet lamp 150, when the chuck 121 is in the second process position P2, may be appropriately set.

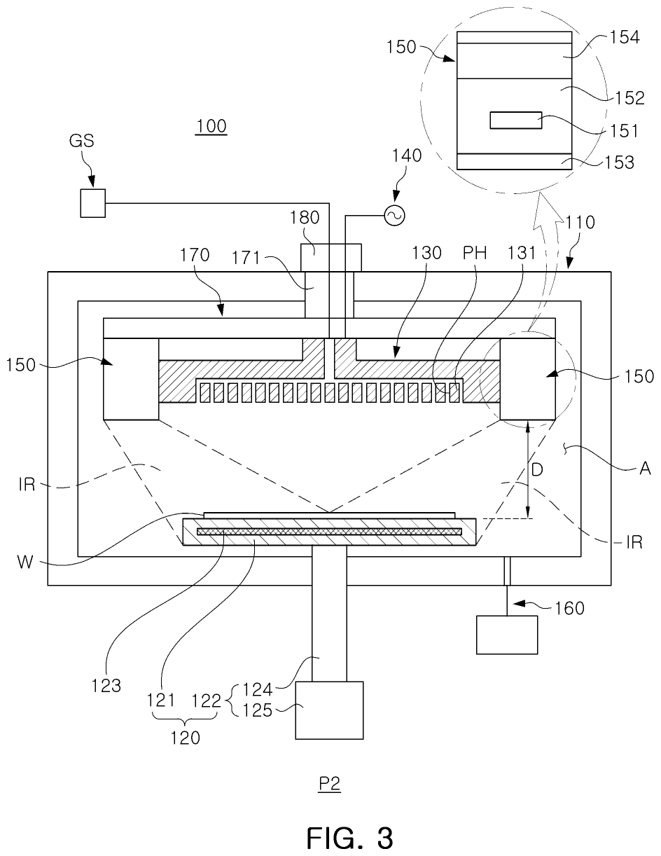

FIG. 3 is a schematic diagram illustrating an example of an ultraviolet lamp in a deposition apparatus according to an example embodiment of the present inventive concept.

Referring to FIG. 3, the ultraviolet lamp 150 may include a lamp bulb 151 radiating ultraviolet rays, a power source supplying power, a reflector 152 surrounding the lamp bulb 151 and reflecting ultraviolet rays, and a light transmitting window 153 disposed between the lamp bulb 151 and the chuck 121 and transmitting ultraviolet rays, which are emitted from the lamp bulb 151, toward the upper surface of the substrate W.

The lamp bulb 151 may emit ultraviolet rays by using the power source. In an example embodiment of the present inventive concept, the lamp bulb 151 may be an H-type ultraviolet lamp bulb. For example, the lamp bulb 151 may be disposed such that it extends horizontally and extends in parallel with the light transmitting window 153.

The lamp bulb 151 may be a sealed plasma bulb filled with one or more gases such as xenon (Xe) or mercury (Hg) for excitation caused by a power source. The power source includes a magnetron 154, and supplies power to the magnetron 154 so that the lamp bulb 151 may emit ultraviolet rays. However, the configuration of the lamp bulb 151 is not limited thereto and may be configured in various forms. In an example embodiment of the present inventive concept, the lamp bulb 151 may include an electrode or a filament therein, and the power source may include a circuit or a current source supplying power to the electrode.

The reflector 152 may reflect ultraviolet rays emitted from the lamp bulb 151 to maximize ultraviolet rays emitted toward the substrate W that is mounted on the chuck 121.

The light transmitting window 153 may be disposed between the lamp bulb 151 and the chuck 121, and may be formed of a material such as quartz glass, silica or the like to transmit ultraviolet rays that are emitted from the lamp bulb 151 toward the upper surface of the substrate W. Ultraviolet rays emitted from the lamp bulb 151 may pass through the light transmitting window 153 and be irradiated onto the upper surface of the substrate W.

According to the configuration of the deposition apparatus 100 according to the above embodiment, deposition when the chuck 121 is in the first process position P1 and annealing treatment when the chuck 121 is in in the second process position P2 are possible according to the lifting motion of the chuck 121 in a single chamber 110, and thus, thin films deposited on the substrate W may be stabilized.

The configuration, structure, and arrangement of the chamber 110, the support unit 120, the showerhead 130, the power supply unit 140, and the ultraviolet lamp 150 of the deposition apparatus 100 illustrated in FIGS. 1 and 2 are examples, and various changes may be made in example embodiments of the present inventive concept.

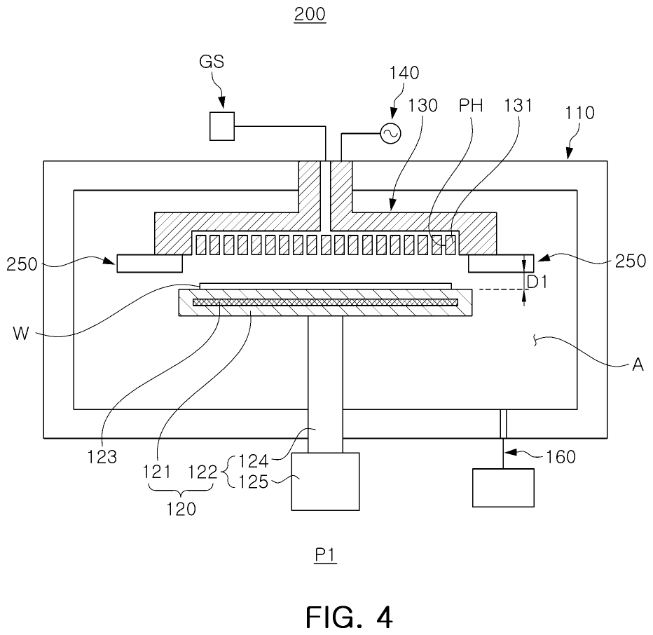

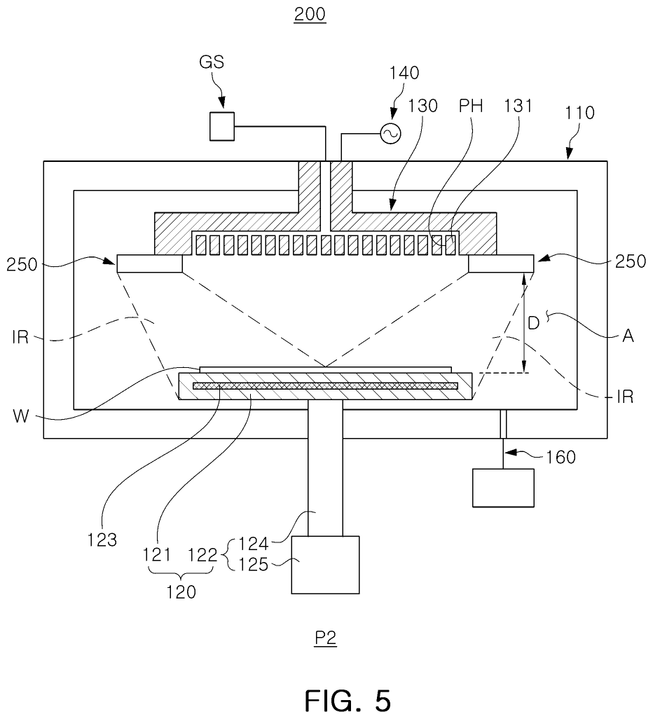

FIG. 4 is a schematic diagram illustrating a deposition apparatus positioned in a first process position according to an example embodiment of the present inventive concept, and FIG. 5 is a schematic diagram illustrating a deposition apparatus positioned in a second process position according to an example embodiment of the present inventive concept.

Referring to FIGS. 4 and 5, in a deposition apparatus 200, unlike the example embodiments of FIGS. 1 and 2, an ultraviolet lamp 250 may emit ultraviolet rays toward the upper surface of the substrate W, when the chuck 121 is located in the second process position P2, while being fixed within the chamber 110. In this case, the ultraviolet lamp 250 may be coupled to the lower edge region of the showerhead 130. For example, when the chuck 121 is located in the second process position P2, the ultraviolet lamp 250 may emit ultraviolet rays toward the upper surface of the substrate W, which is seated on the chuck 121, while being in a fixed state coupled to the lower edge region of the showerhead 130. In an example embodiment of the present inventive concept, when ultraviolet rays are emitted while the ultraviolet lamp 250 is fixed, the chuck 121 of the support unit 120 may perform an annealing process in a rotating or fixed state as needed.

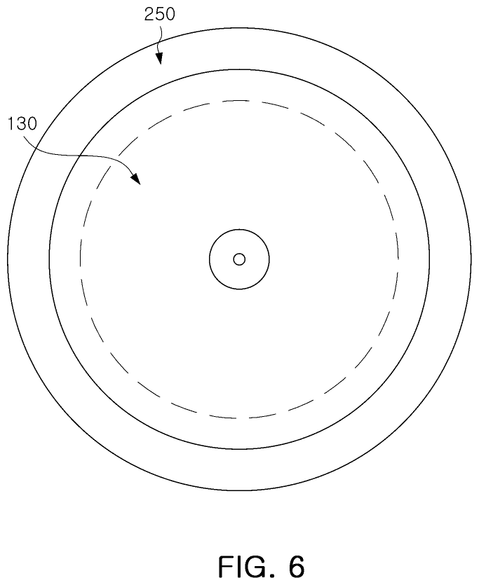

FIG. 6 is a plan schematic diagram illustrating an example of a showerhead and an ultraviolet lamp in a deposition apparatus according to an example embodiment of the present inventive concept.

In an example embodiment of the present inventive concept, when both the ultraviolet lamp 250 and the chuck 121 of the support unit 120 are fixed, the ultraviolet lamp 250 may be disposed with an annular shape along the perimeter of the lower edge region of the showerhead 130 as illustrated in FIG. 6 to uniformly emit ultraviolet rays toward the upper surface of the substrate W. Accordingly, the structure of the deposition apparatus 200 may be simplified and a uniform annealing effect on the substrate may be implemented.

In an example embodiment of the present inventive concept, when annealing is performed while the ultraviolet lamp is fixed and the chuck of the support unit is rotated, the ultraviolet lamp 150 illustrated in FIGS. 1 and 2 or the ultraviolet lamp 250 illustrated in FIG. 6 may be applied depending on an example embodiment of the present inventive concept, but the present inventive concept is not limited thereto. For example, various embodiments of ultraviolet lamps may be applied.

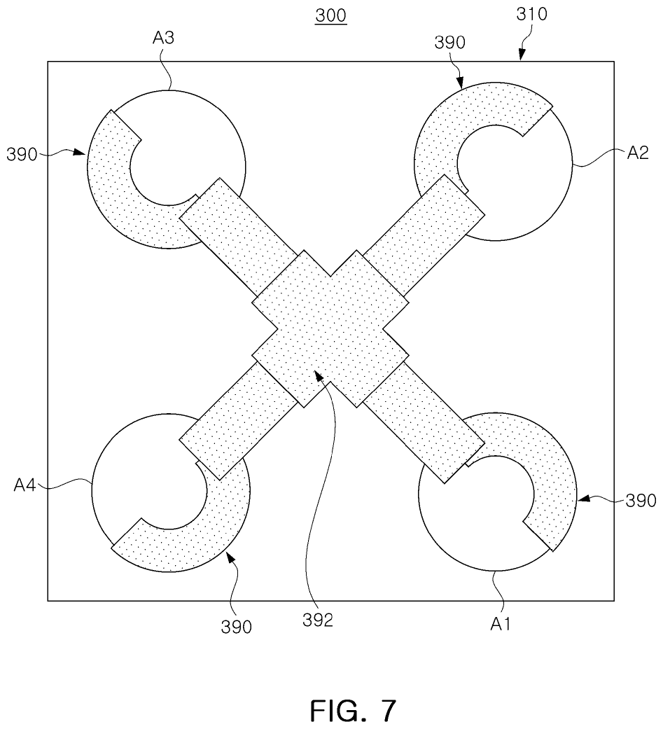

FIG. 7 is a schematic diagram illustrating a deposition apparatus including a chamber with a plurality of processing areas according to an example embodiment of the present inventive concept.

Unlike the example embodiments of FIGS. 1, 2, 4 and 5, a deposition apparatus 300 may include a chamber 310 having a plurality of processing areas.

Referring to FIG. 7, in an example embodiment of the present inventive concept, the deposition apparatus 300 may include the chamber 310 with four processing areas A1, A2, A3 and A4, and a transfer arm 390 disposed within the chamber 310 and transporting the substrate W to the four processing areas A1, A2, A3, and A4. Both the deposition process and the annealing process may be performed in each of the four processing areas A1, A2, A3, and A4 within the chamber 310. The transfer arm 390 may be disposed in the center of the four processing areas A1, A2, A3 and A4 and may transfer the substrate W to the four processing areas A1, A2, A3 and A4. The deposition apparatus 300 may further include a rotation driver 392 rotating the transfer arm 390 to transfer the substrate W from one processing area to another processing area.

Additionally, the deposition apparatus 300 may include a support unit, a showerhead, a power supply unit, an ultraviolet lamp, and an exhaust unit disposed in each of the processing areas A1, A2, A3, and A4, but the present inventive concept is not limited thereto. For example, some of the support unit, the showerhead, the power supply unit, the ultraviolet lamp, or the exhaust unit may be shared between respective processing areas.

The support unit may include a chuck disposed in each of the processing areas A1, A2, A3 and A4 in the chamber 310 and may include a configuration for a deposition position (a first process position P1), in which the substrate is seated on the chuck and the substrate is subjected to a deposition process, and an annealing position (a second process position P2), which is located below the deposition position and in which the substrate is subjected to an annealing process. The support unit may further include a driving member that is connected to the chuck and moves the chuck between the deposition position and the annealing position.

The showerhead is disposed above the chuck within the chamber 310 and may supply process gas toward the upper surface of the substrate that is seated on the chuck, when the chuck is located in the deposition position.

The power supply unit is connected to the showerhead and may supply power to generate plasma in the processing area between the chuck and the showerhead.

The ultraviolet lamp is disposed in the chamber 310 and may emit ultraviolet rays toward the upper surface of the substrate that is seated on the chuck that is located in the annealing position.

The support unit, the showerhead, the power supply unit, the ultraviolet lamp and the exhaust unit may be the same as the support unit 120, the showerhead 130, the power supply unit 140, the ultraviolet lamp 150, and the exhaust unit 160 illustrated in FIGS. 1 and 2, or the support unit 120, the showerhead 130, the power supply unit 140, the ultraviolet lamp 250, and the exhaust unit 160 illustrated in FIGS. 4 and 5, and thus, detailed descriptions thereof may be omitted to prevent redundant descriptions.

In addition, a method of depositing a substrate according to an example embodiment of the present inventive concept is provided.

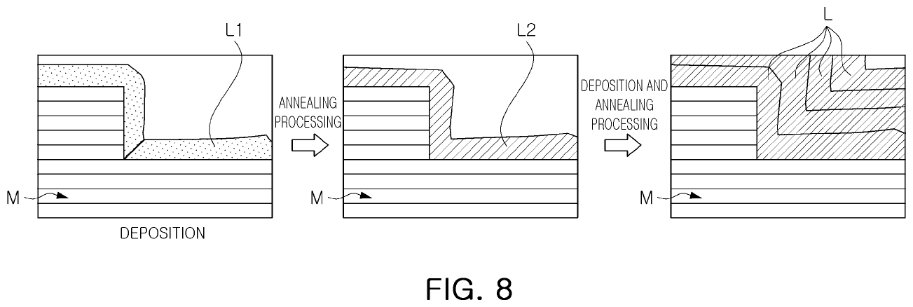

FIG. 8 is a schematic diagram illustrating a substrate deposition process according to an example embodiment.

Referring to FIG. 8, in an example embodiment of the present inventive concept, a method of depositing a substrate may be a method of depositing a substrate by using the deposition apparatus 100 illustrated in FIGS. 1 to 3, the deposition apparatus 200 illustrated in FIGS. 4 to 6, or the deposition apparatus 300 illustrated in FIG. 7. A method of depositing a substrate W according to an example embodiment of the present inventive concept may include a deposition operation of depositing a substrate W that is seated on a chuck 121 that is located in a first process position P1 within the chamber (110, 310). The method may further include, after the deposition operation, an annealing operation of emitting ultraviolet rays toward the upper surface of the substrate W that is seated on the chuck 121 that is located in a second process position P2, which is lower than the first process position P1, by lowering the chuck 121 within the chamber 110 or 310.

In the deposition operation, the substrate W may be deposited by supplying a process gas into the chamber 110 or 310 to generate plasma while the ultraviolet lamp 150 or 250 is turned off. Accordingly, a film L1 may be deposited on the upper portion of the substrate W. In this case, a mold layer M may be formed between the substrate W and the film L1 as illustrated in FIG. 8. For example, as illustrated in FIG. 8, the film L1 may be deposited on the upper surface of the mold layer M that is formed on the upper portion of the substrate W.

In the annealing operation, the annealing process may be performed by emitting ultraviolet rays toward the upper surface of the substrate W by using the ultraviolet lamp 150 or 250 while the supply of the process gas and the generation of plasma are stopped. Accordingly, a cured film L2 may be formed by heating and activating the substrate W and the film L1 that is deposited on the top of the substrate W.

The deposition operation and the annealing operation may be repeatedly performed multiple times within one chamber (110, 310). Accordingly, despite low transmittance of ultraviolet rays, respective films L1 deposited on the upper part of the substrate W through several deposition processes are irradiated with ultraviolet rays through an annealing operation, thereby improving the overall annealing effect and thus forming a stabilized film L of a certain thickness on the substrate W.

According to a deposition apparatus and a method of depositing a substrate according to an example embodiment of the present inventive concept, deposition and annealing processing may be performed in one chamber, thereby stabilizing thin films that are deposited on the substrate.

As set forth above, a deposition apparatus and a method of depositing a substrate, in which thin films that are deposited on a substrate may be stabilized by enabling deposition and annealing processes in a single chamber, may be provided.

While the present inventive concept has been described with reference to embodiments thereof, it will be understood by those of ordinary skill in the art that various changes in form and details may be made thereto without departing from the spirit and scope of the present inventive concept.

What is claimed is:

1. A deposition apparatus comprising:
a chamber;
a support unit within the chamber and including a chuck and a driving member, wherein a substrate is seated on the chuck, wherein the chuck has a first process position and a second process position, wherein the first process position is for processing the substrate in a first process, wherein the second process position is located below the first process position and is for processing the substrate in a second process, wherein the driving member is connected to the chuck and moves the chuck between the first process position and the second process position;
a showerhead disposed to face the chuck and supplying process gas toward an upper surface of the substrate that is seated on the chuck, when the chuck is located in the first process position;
a power supply unit connected to the showerhead and supplying power to generate plasma between the chuck and the showerhead; and
a first ultraviolet lamp disposed above the chuck in the chamber and emitting ultraviolet rays toward the upper surface of the substrate that is seated on the chuck, when the chuck is located in the second process position.

2. The deposition apparatus of claim 1, wherein the first ultraviolet lamp is disposed adjacent to a side surface of the showerhead.

3. The deposition apparatus of claim 2, wherein the first ultraviolet lamp protrudes beyond a lower surface of the showerhead.

4. The deposition apparatus of claim 2, further comprising:
a rotation support member disposed above the showerhead, and having a lower edge region and a rotation axis, wherein the lower edge region is coupled to the first ultraviolet lamp, and wherein the rotation axis is rotatably coupled to the chamber; and
a rotation drive member connected to the rotation axis and rotating the rotation support member and the first ultraviolet lamp around the rotation axis.

5. The deposition apparatus of claim 4, wherein the first ultraviolet lamp is of a plurality of ultraviolet lamps, wherein the plurality of ultraviolet lamps are symmetrical to each other and spaced apart from each other at the lower edge region of the rotation support member with respect to the rotation axis.

6. The deposition apparatus of claim 5, further comprising:
a second ultraviolet lamp, wherein the first ultraviolet lamp and the second ultraviolet lamp are symmetrical to each other and spaced apart from each other at the lower edge region of the rotation support member with respect to the rotation axis.

7. The deposition apparatus of claim 4, wherein the rotation support member has a shape of a disk and covers an upper portion of the showerhead.

8. The deposition apparatus of claim 1, wherein the first ultraviolet lamp is coupled to a lower edge region of the showerhead.

9. The deposition apparatus of claim 8, wherein the first ultraviolet lamp is disposed an annular shape along a circumference of the lower edge region of the showerhead.

10. The deposition apparatus of claim 1, wherein the first ultraviolet lamp includes a lamp bulb emitting ultraviolet rays, a power source supplying power to the lamp bulb, a reflector surrounding the lamp bulb and reflecting ultraviolet rays, and a light transmitting window disposed between the lamp bulb and the chuck and transmitting ultraviolet rays that are emitted from the lamp bulb toward the upper surface of the substrate.

11. The deposition apparatus of claim 10, wherein the lamp bulb is comprised of an H-type ultraviolet lamp bulb.

12. The deposition apparatus of claim 1, wherein the first ultraviolet lamp emits ultraviolet rays with a wavelength of about 150 nm to about 400 nm.

13. The deposition apparatus of claim 1, wherein a separation distance between the chuck and the first ultraviolet lamp is about 15 cm to about 30 cm, when the chuck is in the second process position.

14. A deposition apparatus comprising:
a chamber having a plurality of processing areas;
a transfer arm within the chamber and transferring a substrate to the plurality of processing areas;
a support unit in each of the processing areas, and including a chuck and a driving member, wherein a substrate is mounted on the chuck, wherein the chuck has a deposition position and an annealing position, wherein the deposition position is for a deposition process of the substrate, wherein the annealing position is located below the deposition position and is for an annealing process of the substrate, and wherein the driving member is connected to the chuck and moves the chuck between the deposition position and the annealing position;
a showerhead disposed to be opposite to the chuck in the chamber and supplying process gas toward an upper surface of the substrate that is seated on the chuck, when the chuck is located in the deposition position;
a power supply unit connected to the showerhead and supplying power to generate plasma in a processing area that is between the chuck and the showerhead; and
an ultraviolet lamp disposed in the chamber and emitting ultraviolet rays toward the upper surface of the substrate that is seated on the chuck, when the chuck is located in the annealing position.

15. The deposition apparatus of claim 14, wherein the ultraviolet lamp is disposed adjacent to a side surface of the showerhead and protrudes beyond a lower surface of the showerhead, and
a separation distance between the chuck and the ultraviolet lamp is about 15 cm to about 30 cm, when the chuck is in the annealing position.

16. The deposition apparatus of claim 14, wherein the ultraviolet lamp is disposed adjacent to a side surface of the showerhead,
the deposition apparatus further comprising:
a rotating support member having a lower portion that is coupled to the showerhead, wherein the ultraviolet lamp is coupled to a lower edge region of the showerhead, and wherein the rotation support member is provided with a rotation shaft that is rotatably coupled to the chamber; and
a rotation drive member connected to the rotation shaft and rotating the rotation support member and the ultraviolet lamp around the rotation shaft.

17. The deposition apparatus of claim 14, wherein the ultraviolet lamp is coupled to a lower edge region of the showerhead.

18. The deposition apparatus of claim 14, further comprising a rotation driver rotating the transfer arm and transferring the substrate from one processing area of the plurality of processing areas to another processing area of the plurality of processing areas.

19. A method of depositing a substrate, comprising:
a deposition operation of depositing a substrate that is mounted on a chuck, when the chuck is located in a first process position within a chamber; and
an annealing operation of lowering the chuck within the chamber after the deposition operation is performed and emitting ultraviolet rays toward an upper surface of the substrate that is seated on the chuck, when the chuck is located in a second process position that is lower than the first process position,
wherein the deposition operation and the annealing operation are repeatedly performed multiple times within the chamber.

20. The method of claim 19, wherein in the deposition operation, process gas is supplied into the chamber to generate plasma and the substrate is deposited, and
in the annealing operation, annealing is performed by emitting ultraviolet rays toward the upper surface of the substrate by using an ultraviolet lamp while stopping supply of the process gas and generation of the plasma.
